(19) United States
(12) Patent Application Publication
(10) Pub. No.: US 2005/0062511 A1
(43) Pub. Date: Mar. 24, 2005

(54) Electronic delay element

(75) Inventors: David Jia Chen, Endwell, NY (US); Eugene James Nosowicz, Vestal, NY (US)

Correspondence Address: FLEIT, KAIN, GIBBONS, GUTMAN, BONGINI;& BIANCO P.L., ONE BOCA COMMERCE CENTER, 551 NORTHWEST 77TH STREET, SUITE 111, BOCA RATON, FL, 33487, US

(73) Assignee: INTERNATIONAL BUSINESS MACHINES CORPORATION, ARMONK, NY (US)

(21) Appl. No.: 10/665,654

(22) Filed: Sep. 18, 2003

(51) Int. Cl. H03H 11/26

(52) U.S. Cl. 327/277

(57) ABSTRACT

A delay element for use in circuit designs. The delay element accepts an input signal, typically a clock signal, and provides a delay of that signal to adjust path timing such as is used for the clocking of imbedded arrays of integrated circuits. By using uniform channel length devices, the delay element provides enhanced tuning and tracking of device parameters of the timing circuit as well as simplifying modeling of the delay element circuit.

### BACKGROUND OF THE INVENTION

1. Field of the Invention

This invention relates to digital circuitry and more specifically to electronic delay elements on integrated circuits.

2. Description of Related Art

Electronic circuit designs typically include arrangements for synchronizing operations of digital circuits. It is common to provide one or more clocks for control of the timing operation of most digital circuits. However, a complicating factor in the design of digital circuits is that clock signals are subject to propagation delays and other forms of distortion as they are distributed to various elements of a digital circuit. Typically, electronic delay elements are used on integrated circuits to adjust path timing or to generate extended pulses used for clocking imbedded arrays.

Elements that can generate extended delays are difficult to design and fabricate. One traditional delay element comprised a series of inverter gates. These inverter delay line configurations used significantly more space (approximately four times) and more power than the conventional type of delay element shown in FIG. 2.

A block diagram of a delay element 100 used in digital circuits is shown in FIG. 1. The exemplary delay element 100 includes a series of delay stages, delay stage TD1 104, delay stage TD2 106, delay stage TD3 108, delay stage TD4 110, delay stage TD5 112, delay stage TD6 114, delay stage TD7 116, and delay stage TD8 118. The first delay stage TD1 104 has an input signal CLKIN 102. The input signal CLKIN 102 is delayed for a predetermined amount of time and then output as TD1OUT 120, which in turn drives the input of the second delay stage TD2 106. TD1OUT 120 is delayed for a predetermined amount of time and then output as TD2OUT 122, which in turn drives the input of the third delay stage TD3 108. TD2OUT 122 is delayed for a predetermined amount of time and then output as TD3OUT 124, which in turn drives the input of the fourth delay stage TD4 110. TD3OUT 124 is delayed for a predetermined amount of time and then output as TD4OUT 126, which in turn drives the input of the fifth delay stage TD5 112. TD4OUT 126 is delayed for a predetermined amount of time and then output as TD5OUT 128, which in turn drives the input of the sixth delay stage TD6 114. TD5OUT 128 is delayed for a predetermined amount of time and then output as TD6OUT 130, which in turn drives the input of the seventh delay stage TD7 116 TD6OUT 130 is delayed for a predetermined amount of time and then output as TD7OUT 132, which in turn drives the input of the eighth delay stage TD8 118 TD7OUT 132 is delayed for a predetermined amount of time and then output as CLKOUT 134. These stages may be comprised of a virtually any circuit element such as a transistor having a finite signal propagation time. Furthermore, the delay element 100 does not require a large number of stages and, in fact, might be reduced to one stage at extreme clock frequencies.

An exemplary prior art delay element circuit 200 for the delay element 100 is illustrated in FIG. 2. The prior art delay element circuit 200 has prior art delay stages DLY1 234, DLY2 236, DLY3 238, DLY4 240, DLY5 242, DLY6 244, DLY7 246 and DLY8 248, which perform the functions of TD1 104, TD2 106, TD3 108, TD4 110, TD5 112, TD6 114, TD7 116, and TD8 118, respectively, of the delay element 100. An examination of the prior art delay element circuit 200 reveals that each prior art delay stage, DLY1 234 through DLY8 248, is comprised of two FET devices of which one FET device is a minimum channel length device (l=80 n) and the other FET device is an extended channel length device (l=280 n). For example, prior art delay stage DLY1 234 is comprised of FET device TPDLY1 202, which is an extended channel length device (l=280 n) stacked with a FET device TNDLY1 204, which is a minimum channel length device (l=80 n). Similarly, prior art delay stage DLY2 236 is comprised of FET device TPDLY2 206, which is a minimum channel length device (l=80 n) stacked with a FET device TNDLY2 208, which is an extended channel length device (l=280 n). This pattern of alternating minimum channel length devices (l=80 n) with extended channel length devices (l=280 n), follows for the remaining prior art delay stages DLY3 238 through DLY8 248.

The use of various channel length devices, as indicated in the prior art delay element 200, creates problems in the modeling and processing of integrated circuits. Typically in production, the process is “tuned” to be optimal for a given channel length. Consequently, this results in variations of channels that are outside the “tuned range.” The process in the prior art cannot be tuned to accommodate these high degrees of variation.

Across chip length variation (ACLV) is typically a fixed number in a production process. For example, an 80-nanometer channel length with a tolerance of 10-nanometer yields a 10/80 (12.5%) variation across chips. Comparing this to an extended channel length of 280 nanometers, which provides a tolerance of 10/280 or 3.6%. This mixture of channel lengths results in non-uniform tolerance variations across the circuit. Accordingly, the tolerances across the delay stages will not properly track the tolerances of other circuits on the chips. This is especially a problem with timing elements, since delays through delay circuits with extended channel lengths will vary across the chip by a different amount than other circuits with all minimum length elements.

What is therefore needed is a delay element design that increases parametric tracking of device characteristics, increases chip yield, and provides for enhanced modeling of circuit designs.

### SUMMARY OF THE INVENTION

The exemplary embodiments of the present invention overcome the problems of the prior art by providing a delay element for use in integrated circuits that increases parametric tracking and uses standard modeling techniques. The exemplary embodiment of the present invention replaces the prior art delay stages containing various channel length devices with stacks of minimum channel length devices. This results in a similar stage delay when compared to the prior art stages DLY1 234 through DLY8 248, but eliminates the need for extended channel length devices. Although there are more minimum length channel devices used by the exemplary embodiment, these minimum length channel devices are physically smaller and use basically an equivalent amount of chip (silicon) area.

An exemplary embodiment of the present invention relates to a delay element with an input signal to be delayed; and a series of at least one delay stages. Each delay stage can comprise a stack of uniform minimum channel length transistors. Each of the transistors can include a gate, a source and a drain. The gates of each of the transistors in each delay stage can be electrically coupled together to form an input in the delay stage. The drain of a top transistor in the stack can be coupled to a first reference voltage (e.g., Vdd), while the source of a bottom transistor in the stack can be coupled to a second reference voltage (e.g., GND). The source of the top transistor can be electrically coupled to the drain of the bottom transistor in the stage so as to form an output of the stage.

The foregoing and other features and advantages of the present invention will be apparent from the following more particular description of the preferred embodiments of the invention, as illustrated in the accompanying drawings.

### BRIEF DESCRIPTION OF THE DRAWINGS

The subject matter that is regarded as the invention is particularly pointed out and distinctly claimed in the claims at the conclusion of the specification. The foregoing and other features and also the advantages of the invention will be apparent from the following detailed description taken in conjunction with the accompanying drawings. Additionally, the left-most digit of a reference number identifies the drawing in which the reference number first appears unless additional reference numbers are required.

FIG. 1 is a block diagram of a delay element for use in integrated circuits, as used by an exemplary embodiment of the present invention.

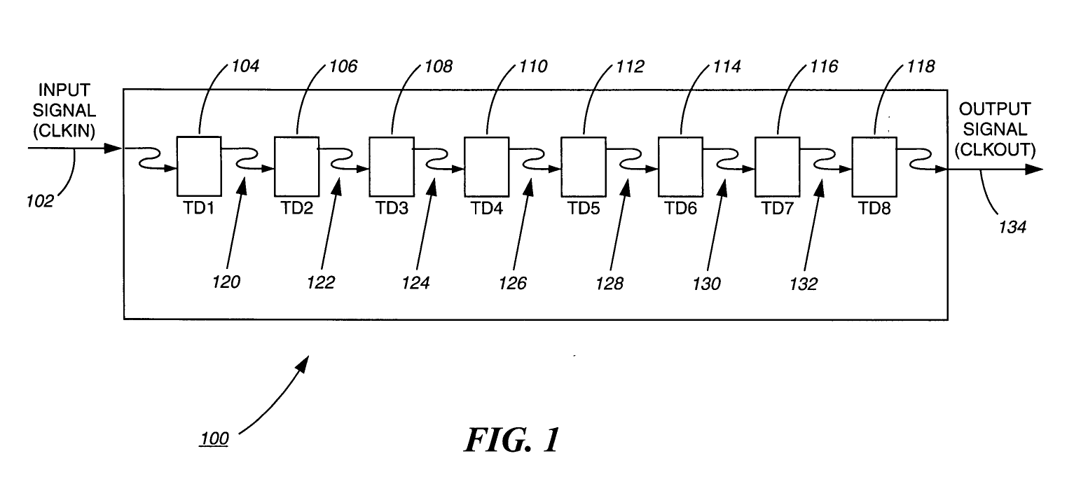

FIG. 2 is a circuit diagram depicting a prior art data delay element with a structure based upon the block diagram shown in FIG. 1.

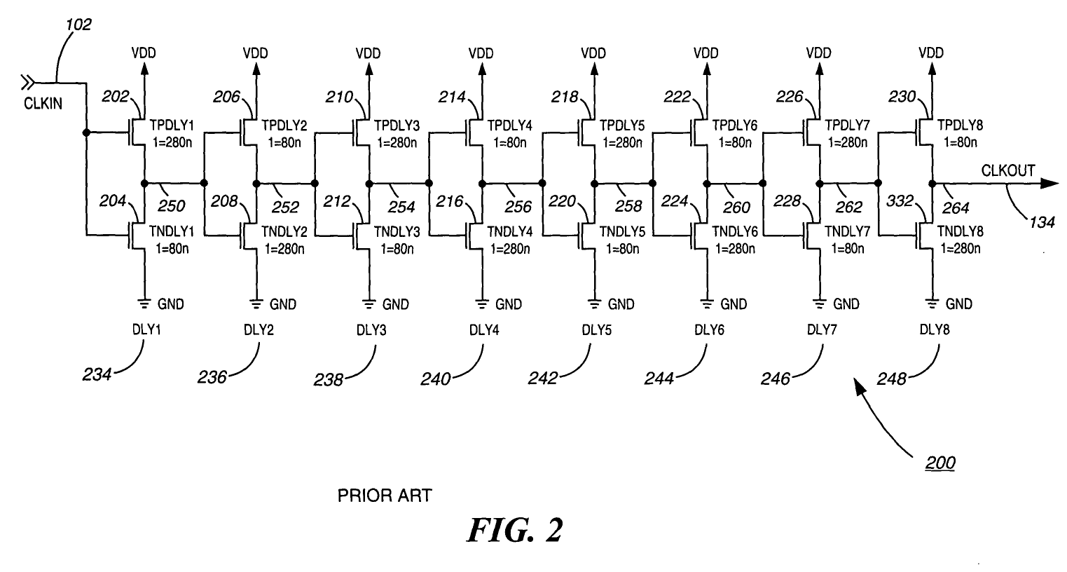

FIG. 3 is a delay element circuit, according to an exemplary embodiment of the present invention.

### DESCRIPTION OF THE PREFERRED EMBODIMENTS

The present invention, according to a preferred embodiment, overcomes problems with the prior art by providing a delay element for use in integrated circuits that increases parametric tracking of device characteristics, increases chip yield, and provides for enhanced modeling of circuit designs. The exemplary embodiments of the present invention eliminate the extended channel length devices used in conventional delay elements with stacks of minimum channel length devices. Although there are more minimum channel length devices used in the new delay element of the exemplary embodiment, due to smaller physical size of the minimum channel length devices, the total area required for the delay element is basically equivalent to the prior art delay element. The minimum and extended channel length devices are typically FET transistors where each transistor includes a gate, a source and a drain. A FET transistor may have its drain electrically coupled to a first reference voltage (e.g. Vdd) and a second reference voltage (e.g. GND). Additionally a FET transistor may have its source electrically coupled to a first reference voltage (e.g. Vdd) and a second reference voltage (e.g. GND). The selection of a voltage reference for electrical coupling with a drain or source will depend on the circuit configuration, as well as the type of FET transistor. As is well known there are two basic types of FETs, the n-channel FET and the p-channel FET.

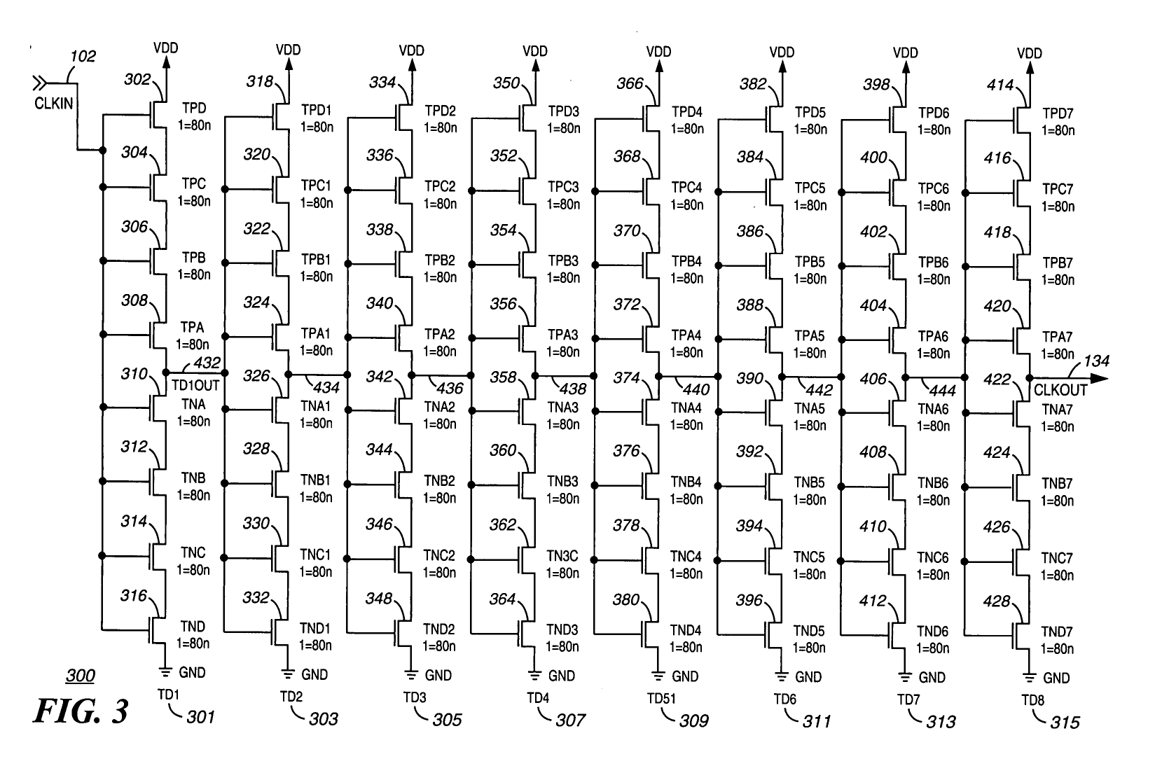

An improved delay element circuit 300 as is used by an exemplary embodiment of the present invention is illustrated in FIG. 3. The improved delay element circuit 300 has delay stages TD1 301, TD2 303, TD3 305, TD4 307, TD5 309, TD6 311, TD7 313, and TD8 315, which perform the functions of TD1 104, TD2 106, TD3 108, TD4 110, TD5 112, TD6 114, TD7 116, and TD8 118, respectively, of the delay element 100.

Each delay stage of the improved delay element circuit 300 is comprised of a uniform stack or totem pole of a series of minimum channel length devices (l=80 n). In this example eight devices are shown. It is important to note that any number of devices may be used within the true scope and spirit of the present invention. The use of uniform minimum channel length devices greatly enhances the tuning and tracking of device parameters of the circuit over the prior art delay element circuit 200 and advantageously improves modeling of the delay element circuit. For example, new delay stage TD1 301 is comprised of eight minimum channel length (l=80 n) devices TPD 302, TPC 304, TPB 306 TPA 308, TNA 310, TNB 312, TNC 314 AND TND 316. All inputs of each device in the stack of delay stage TD1 301 are connected together in parallel to increase the load (delay) for the previous stage driving it. Here the input to each device is CLKIN 102. The output of TD1 301 is TD1OUT 432, which serves as the input for TD2 303.

New delay stage TD2 303 of the exemplary embodiment is comprised of eight minimum channel length (l=80 n) devices TPD1 318, TPCI 320, TPB1 322, TPA1 324, TNA1 326, TNB1 328, TNC1 330 AND TND1 332. All inputs of each device in the stack of delay stage TD2 303 are connected together in parallel to increase the load (delay) for the previous stage driving it. The output of TD2 303 is TD2OUT 434, which serves as the input for TD3 305.

New delay stage TD3 305 of the exemplary embodiment is comprised of eight minimum channel length (l=80 n) devices TPD2 334, TPC2 336, TPB2 338, TPA2 340, TNA2 342, TNB2 344, TNC2 346 AND TND2 348. All inputs of each device in the stack of delay stage TD3 305 are connected together in parallel to increase the load (delay) for the previous stage driving it. The output of TD3 303 is TD3OUT 436, which serves as the input for TD4 307.

New delay stage TD4 307 of the exemplary embodiment is comprised of eight minimum channel length (I=80 n) devices TPD3 350, TPC3 352, TPB3 354, TPA3 356, TNA3 358, TNB3 360, TNC3 362 AND TND3 364. All inputs of each device in the stack of delay stage TD4 307 are connected together in parallel to increase the load (delay) for the previous stage driving it. The output of TD4 307 is TD4OUT 438, which serves as the input for TD5 309.

New delay stage TD5 309 of the exemplary embodiment is comprised of eight minimum channel length (l=80 n) devices TPD4 366, TPC4 368, TPB4 370, TPA4 372, TNA4 374, TNB4 376, TNC4 378 AND TND4 380. All inputs of each device in the stack of delay stage TD5 309 are connected together in parallel to increase the load (delay) for the previous stage driving it. The output of TD5 309 is TD4OUT 438, which serves as the input for TD6 311.

New delay stage TD6 311 of the exemplary embodiment is comprised of eight minimum channel length (l=80 n) devices TPD5 382, TPC5 384, TPB5 386, TPA5 388, TNA5 390, TNB5 392, TNC5 394 AND TND5 396. All inputs of each device in the stack of delay stage TD6 311 are connected together in parallel to increase the load (delay) for the previous stage driving it. The output of TD6 311 is TD6OUT 442, which serves as the input for TD7 313.

New delay stage TD7 313 of the exemplary embodiment is comprised of eight minimum channel length (I=80 n) devices TPD6 398, TPC6 400, TPB6 402, TPA6 404, TNA6 406, TNB6 408, TNC6 410 AND TND6 412. All inputs of each device in the stack of delay stage TD7 313 are connected together in parallel to increase the load (delay) for the previous stage driving it. The output of TD7 313 is TD7OUT 444, which serves as the input for TD8 315.

New delay stage TD8 315 of the exemplary embodiment is comprised of eight minimum channel length (I=80 n) devices TPD7 414, TPC7 416, TPB7 418, TPA7 420, TNA7 422, TNB7 424, TNC7 426 AND TND7 428. All inputs of each device in the stack of delay stage TD8 315 are connected together in parallel to increase the load (delay) for the previous stage driving it. The output of TD8 315 is CLKOUT 134.

The delay elements described above are incorporated into a wide variety of digital circuits. For example, delay elements are used in clock circuits as pulse extenders/choppers for Static Random Access Memory (SRAM) devices. It is apparent that all circuits using delay elements benefit from the use of the improved delay element circuit 300 or similar embodiments of the present invention.

Although specific embodiments of the invention have been disclosed, those having ordinary skill in the art will understand that changes can be made to the specific embodiments without departing from the spirit and scope of the invention. The scope of the invention is not to be restricted, therefore, to the specific embodiments. Furthermore, it is intended that the appended claims cover any and all such applications, modifications, and embodiments within the scope of the present invention.

1. A delay element, comprising:
an input signal to be delayed; and
a series of at least two delay stages;
wherein each delay stage includes a stack of uniform minimum channel length transistors selected from one of a first conductivity type and a second conductivity type;
wherein a gate of each of the transistors in each delay stage are electrically coupled together to form an input in the delay stage;
wherein a drain of a top transistor in the stack is coupled to a first reference voltage;
wherein a source of a bottom transistor in the stack is coupled to a second reference voltage;
wherein a source of the top transistor is electrically coupled to a drain of the bottom transistor in the stage so as to form an output of the stage;
wherein when the input signal to be delayed is in a low state each transistor of the first conductivity type is active and each transistor of the second conductivity type is inactive; and
wherein when the input signal to be delayed is in a high state, each transistor of the first conductivity type is inactive and each transistor of the second conductivity type is active.

2. The delay element according to claim 1, wherein each stack of transistors includes additional transistors electrically coupled with the top transistor and the bottom transistor;
wherein a drain of a first additional transistor is electrically coupled to a source of the top transistor, a source of the last additional transistor is connected to a drain of the bottom transistor; and
wherein a drain of each of zero or more remaining additional transistors is electrically coupled to a source of an adjacent transistor within the remaining additional transistors so as to form a totem pole configuration for the stack.

3. The delay element according to claim 1, wherein each transistor is a n-channel FET.

4. The delay element according to claim 1, wherein each transistor is a p-channel FET.

5. The delay element according to claim 2, wherein each transistor is a n-channel FET.

6. The delay element according to claim 2, wherein each transistor is a p-channel FET.

7. The delay element according to claim 1, wherein the input signal to be delayed is a clock signal.

8. The delay element according to claim 2, wherein the input signal to be delayed is a clock signal.

9. A memory circuit comprising:
at least one delay element; wherein the delay element includes:
an input signal to be delayed; and
a series of at least two delay stages;
wherein each delay stage includes a stack of uniform minimum channel length transistors selected from one of a first conductivity type and a second conductivity type;
wherein a gate of each of the transistors in each delay stage are electrically coupled together to form an input in the delay stage;
wherein a drain of a top transistor in the stack is coupled to a first reference voltage;
wherein a source of a bottom transistor in the stack is coupled to a second reference voltage;
wherein a source of the top transistor is electrically coupled to a drain of the bottom transistor in the stage so as to form an output of the stage;
wherein when the input signal to be delayed is in a low state, each transistor of the first conductivity type is active and each transistor of the second conductivity type is inactive: and
wherein when the input signal to be delayed is in a high state, each transistor of the first conductivity type is inactive and each transistor of the second conductivity type is active.

10. A clock circuit comprising:
at least one delay element, wherein each delay element includes:
an input signal to be delayed; and
a series of at least two delay stages;
wherein each delay stage includes a stack of uniform minimum channel length transistors selected from one of a first conductivity type and a second conductivity type;
wherein a gate of each of the transistors in each delay stage are electrically coupled together to form an input in the delay stage;
wherein a drain of a top transistor in the stack is coupled to a first reference voltage;
wherein a source of a bottom transistor in the stack is coupled to a second reference voltage;
wherein a source of the top transistor is electrically coupled to a drain of the bottom transistor in the stage so as to form an output of the stage;
wherein when the input signal to be delayed is in a low state, each transistor of the first conductivity type is active and each transistor of the second conductivity type is inactive; and
wherein when the input signal to be delayed is in a high state, each transistor of the first conductivity type is inactive and each transistor of the second conductivity type is active.

11. A delay circuit comprising at least one stack of transistors, each of the at least one stack of transistors comprising:
a first transistor with a drain electrically coupled to a first reference voltage;
a last transistor with a source electrically coupled to a second reference voltage;
a totem pole of at least two transistors, the totem pole including:
a top transistor with a drain electrically coupled to a source of the first transistor;
a bottom transistor with a source electrically coupled to a drain of the last transistor, and
at least two transistors, wherein the transistors complete the totem pole arrangement, wherein a drain of each of the transistors is electrically coupled to a source of an adjacent transistor within the transistors relative to the each of the transistors, and wherein each of the transistors within the totem pole comprise a minimum channel length transistor selected from one of a first conductivity type and a second conductivity type;
an input electrically coupled to each gate within the totem pole; and
an output electrically coupled to connection between one source and one drain of two transistors within the totem pole;
wherein when the input is in a low state, each transistor of the first conductivity type is active and each transistor of the second conductivity type is inactive: and
wherein when the input to be delayed is in a high state, each transistor of the first conductivity type is inactive and each transistor of the second conductivity type is active;

12. The delay circuit according to claim 11, wherein each transistor is a p-channel FET.

13. The delay circuit according to claim 11, wherein each transistor is a n-channel FET.

14. The delay circuit according to claim 11, wherein the input signal to be delayed is a clock signal.
